(19) United States
(12) Patent Application Publication
(10) Pub. No.: US 2007/0152326 A1
(43) Pub. Date: Jul. 5, 2007

(54) Encapsulated external stiffener for flip chip package

(76) Inventors: Chia Ni Lim, Selangor (MY); Chun Hwa See, Tanjung Bunga (MY); Tze Yang Hin, Bayan Lepas (MY)

Correspondence Address: INTEL CORPORATION;c/o INTELLEVATE, LLC, P.O. BOX 52050, MINNEAPOLIS, MN, 55402, US

(21) Appl. No.: 11/322,438

(22) Filed: Dec. 29, 2005

(51) Int. Cl. H01L 23/34

(52) U.S. Cl. 257/723

(57) ABSTRACT

The present invention relates to an external stiffener featuring reinforcing bars and a polymer and a method to make the same. In an embodiment, the stiffener may be used to decrease warpage in the package substrate caused by high temperature processing. In an embodiment, the reinforced bars are disposed over the die attach side of the package substrate. In an embodiment, the polymer may encapsulate a semiconductor die coupled to a package substrate.

### BACKGROUND

1. Field

The present invention relates to the application of structures and materials used to provide mechanical support for package substrate.

2. Description of Related Art

Package substrates typically suffer from warpage due to high temperature processing and thermal cycling during die-attach, pre-bake, or underfill curing. Typically, the core of package substrates may incorporate material with a high Young's modulus to maintain the co-planarity of the package substrate. The addition of high Young's modulus material within the core of package substrate may incur additional cost.

Peripheral external stiffeners have been used to reduce warpage in package substrates. The application of peripheral external stiffeners to package substrates may limit the number of die side capacitors and may also confine them to an area near the center of package substrate proximate a semiconductor die.

### BRIEF DESCRIPTION OF THE DRAWINGS

FIG. 1A is a cross-sectional illustration of a package substrate featuring a semiconductor die, die side capacitors, and a stiffener having reinforcing bars and a polymer according to an embodiment of the present invention.

FIG. 1B is a top view illustration of a package substrate featuring a semiconductor die, die side capacitors, and a stiffener having a package substrate and a polymer according to an embodiment of the present invention.

FIGS. 2A-2C are top view illustrations of various layouts of a reinforcing bars coupled to a package substrate according to an embodiment of the present invention.

FIGS. 3A and 3B are illustrations of various shapes, sizes, and dimensions of reinforcing bars according to an embodiment of the present invention.

FIG. 4A is a cross-sectional illustration of a package substrate featuring die side capacitors and a stiffener having a package substrate and a polymer encapsulating a semiconductor die.

FIG. 4B is a cross-sectional illustration of a package substrate featuring die side capacitors and a stiffener having reinforcing bars and a polymer which does not encapsulate a semiconductor die.

FIG. 5 is an illustration of a chart that lists some material properties of a stiffener featuring a polymer and different concentrations of copper reinforcement bars according to an embodiment of the present invention.

FIGS. 6A-6E, and 7A-7E are illustrations of methods to form a package substrate featuring a stiffener having reinforcing bars and a polymer according to embodiments of the present invention.

### DETAILED DESCRIPTION OF THE PRESENT INVENTION

In an embodiment, the present invention includes a stiffener featuring reinforcing bars and a polymer and a method of making the same. In an embodiment, the reinforcing bars increase the mechanical strength of the stiffener. In an embodiment, the reinforcing bars may be in the form of a mesh such that a network of reinforcing bars is encapsulated in the polymer. In an embodiment, a stiffener featuring reinforcing bars and a polymer is applied to a package substrate. In yet another embodiment, an electronic package includes a package substrate having a stiffener featuring reinforcing bars and a polymer. In an embodiment of the present invention, the stiffener may be used to provide mechanical support for package substrates to prevent warpage, which may improve co-planarity.

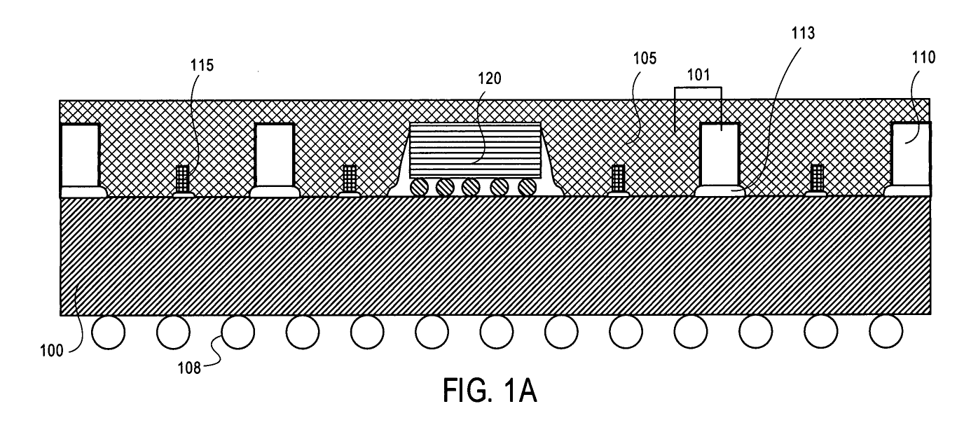

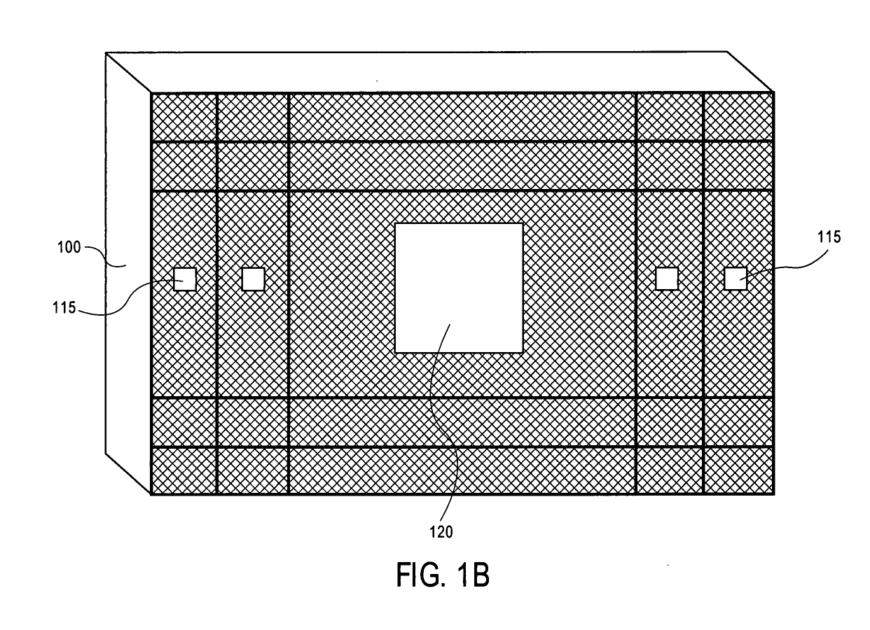

In an embodiment as depicted in the cross-sectional illustration in FIG. 1A, a package substrate 100 includes a semiconductor die 120, die side capacitors 115, ball grid array 108 and a stiffener 101 featuring reinforcing bars 110 and a polymer 105. In an embodiment, reinforcing bars 110 are disposed on the die attach side of package substrate 100 as depicted in the top view illustration in FIG. 1B. In an embodiment as further illustrated in FIG. 1B, die side capacitors 115 are affixed next to reinforcing bars 110. In an embodiment, polymer 105 encapsulates reinforcing bars 110, die side capacitors 115, and semiconductor die 120 as illustrated in FIG. 1A.

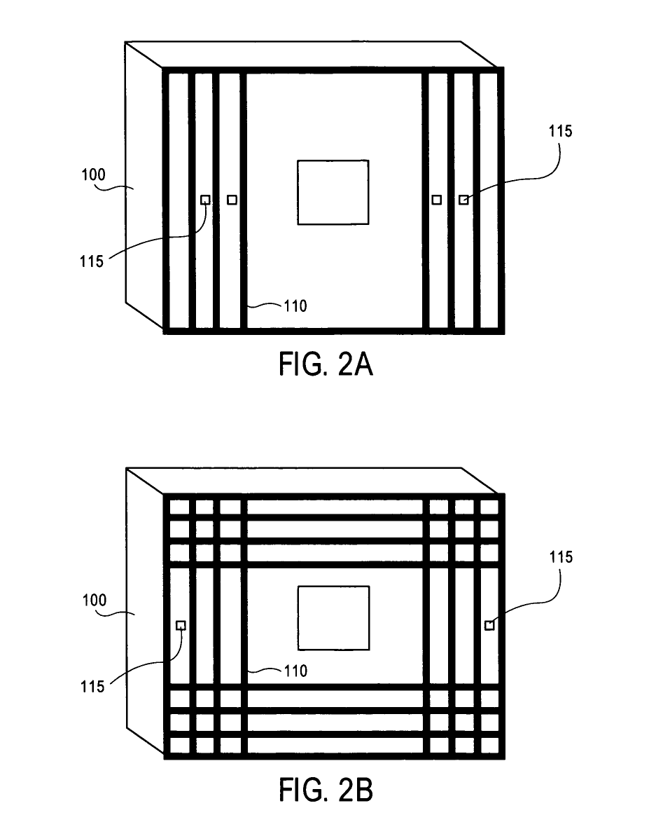

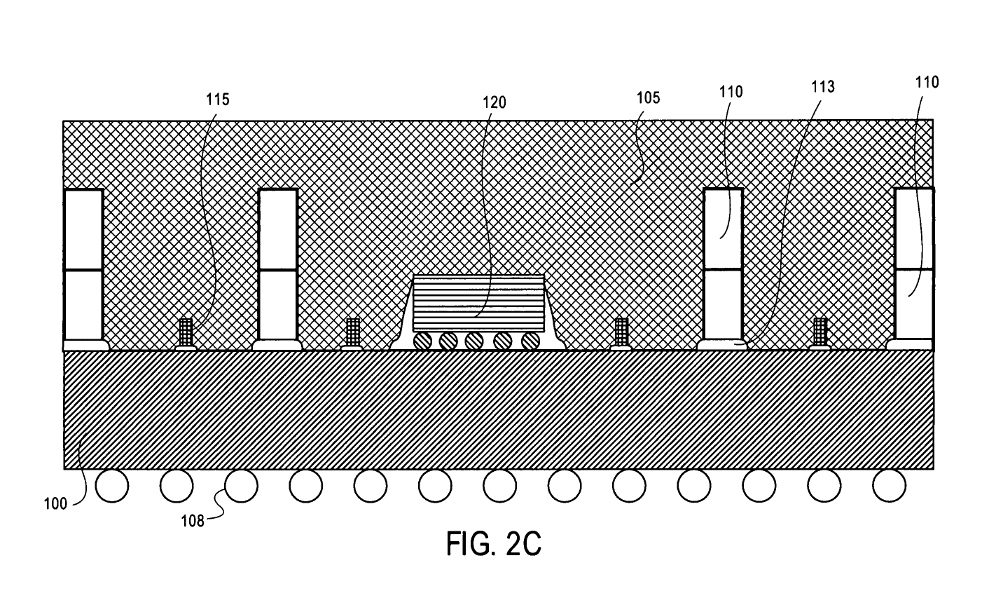

FIGS. 2A-2C illustrate several layouts of reinforcing bars 110 disposed on the die attach side of package substrate 100. In an embodiment as illustrated in FIG. 2A, a plurality of parallel reinforcing bars 110 are disposed on the die attach side of package substrate 100. In an embodiment when a plurality of reinforcing bars 110 are disposed parallel on the die attach side of package substrate 100, reinforcing bars 110 may be spaced equally apart. Reinforcing bars 110 may be spaced apart in a range from 2 mm to 5 mm. In an embodiment, reinforcing bars 110 are spaced 4 mm apart. In an embodiment when reinforcing bars 110 are spaced equally apart, there are equal number of reinforcing bars 110 disposed on package substrate 100 on both sides of semiconductor die 120. In an embodiment, reinforcing bars 110 are not spaced equally apart such that there is not an equal number of reinforcing bars 110 on either side of semiconductor die 120.

In an embodiment, the layout of reinforcing bars 110 on the die attach side of package substrate 100 is in the form of a mesh as illustrated in FIG. 2B. In an embodiment, a mesh is a web-like pattern of reinforcing bars 110 disposed on package substrate 100. A mesh of reinforcing bars 110 may be disposed on package substrate 100 as a single unit or reinforcing bars 110 or may be disposed on package substrate 100 as a plurality of connected reinforcing bars 110. In an embodiment, reinforcing bars 110 are disposed on package substrate 100 as a mesh of connected reinforcing bars 110.

In an embodiment, the layout of reinforcing bars 110 on the die attach side of package substrate 100 may have multiple levels of reinforcing bars 110 as illustrated in FIG. 2C. In an embodiment when there are multiple levels of reinforcing bars 110 each level may have a unique layout. For example, the first level, adjacent to the die attach side of package substrate 100, may be configured as a plurality of parallel reinforcing bars 110. The next level, adjacent to the first level, may be configured as a mesh of reinforcing bars 110. In an embodiment, as illustrated in FIG. 2C, the first level is configured as a parallel layout of reinforcement bars 110 and the second level is configured as a mesh of reinforcing bars 110. In other embodiments, both levels are configured as a mesh of reinforcing bars 110. In an embodiment, levels of reinforcing bars 110 may be coupled by a reflow-solder alloy process.

In an embodiment, the layout of reinforcing bars 110 is configured such that an area is reserved for subsequent semiconductor attachment to package substrate 100. In an embodiment, the area reserved for subsequent semiconductor attachment, reserved area 112, located in a cavity in the layout of reinforcing bars 110 as illustrated in FIGS. 2A-2C.

Die side capacitors 115 may be affixed between or next to reinforcing bars 110. In an embodiment, die side capacitors 115 are affixed between reinforcing bars 110. In an embodiment, higher I/O is achieved when die side capacitors 115 are affixed between reinforcing bars 110 because both parallel and mesh layout of reinforcing bars 110 provide greater area for die side capacitors 115 on package substrate 100. There may be 10 to 80 die side capacitors affixed to package substrate 100. In an embodiment, approximately 40 die side capacitors are affixed to package substrate 100.

Reinforcing bars 110 may consist of any material such that mechanical support is provided for package substrate 100. In an embodiment, reinforcing bars 110 consist of metal. Reinforcing bars 110 may consist of copper, aluminum, or combinations of metal such as steel, tin, or tin-antimony. In an embodiment, reinforcing bars 110 consists of copper.

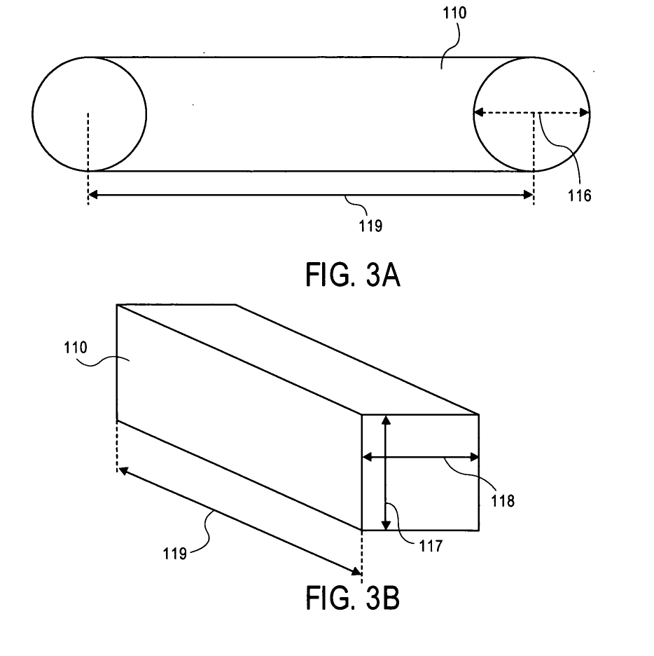

Reinforcing bars 110 may have varying shapes, sizes, and dimensions as illustrated in FIGS. 3A-3B. In an embodiment as illustrated in FIG. 3A, reinforcing bars 110 have a cylindrical shape with a diameter 116 and length 119. Diameter 116 has a range from 200 to 800 μm. In an embodiment, diameter 116 is 400 μm. In other embodiments, reinforcing bars 110 have a cuboid shape with a height 117, width 118, and length 119 as illustrated in FIG. 3B. Height 117 and width 118 may have a range from 200 to 800 μm and from 200 to 2000 μm respectively. In an embodiment, height 117 and width 118 is 400 μm and 400 μm respectively. Length 119 may have a range from 5 to 50 mm. In an embodiment, length 119 is 35 mm.

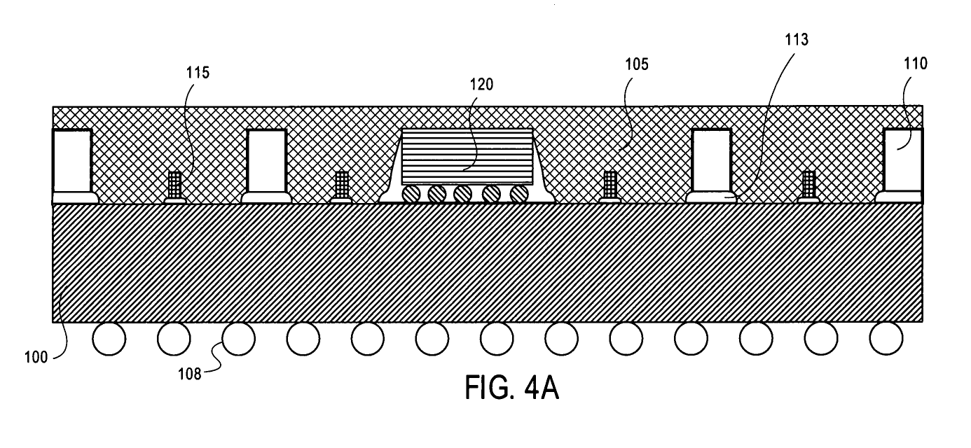

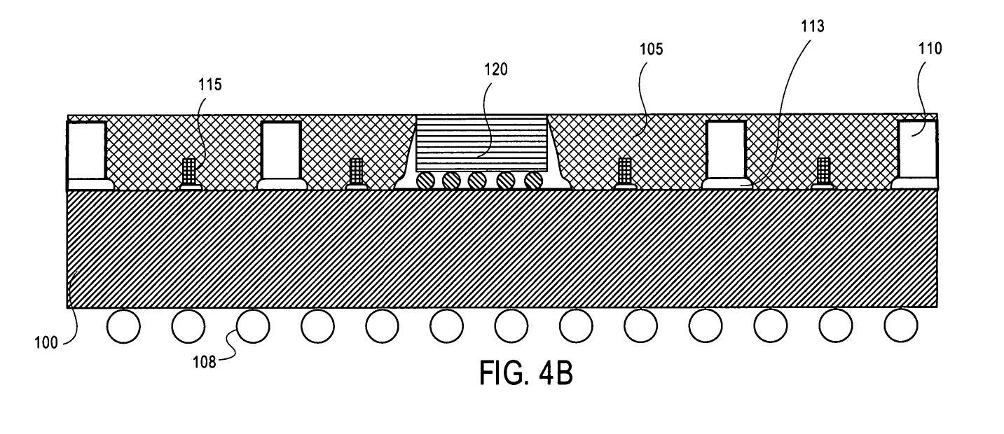

In an embodiment as illustrated in FIG. 4A, the polymer 105 portion of stiffener 101 encapsulates semiconductor die 120. In an embodiment as further illustrated in FIG. 4A, polymer 105 encapsulates die side capacitors 115 and reinforcing bars 110.

However in some embodiments, the polymer 105 portion of stiffener 101 may not encapsulate semiconductor die 120 as illustrated in FIG. 4B. In an embodiment as further illustrated, only die side capacitors 115 and reinforcing bars 110 are encapsulated by polymer 105.

In an embodiment, polymer 105 may consist of any suitable material such that polymer 105 exhibits sufficient stiffening, adhesion, and viscosity properties. Polymer 105 may consist of anhydrate, phenolic, or amine. In an embodiment, polymer 105 consists of a mixture of biphenol and amine epoxy resin. In an embodiment, fillers may be incorporated to enhance the stiffening effect of polymer 105. In an embodiment, a 30% weight fraction of silica filled particles are incorporated in polymer 105 to increase the stiffening effect of polymer 105 by approximately 50%. Other filler materials such as, but not limited to alumina, titanium oxide, or zinc oxide may also be incorporated to increase the stiffening effect of polymer 105.

In an embodiment, polymer 105 can be optimized to adhere to package substrate 100, reinforcing bars 110, and die side capacitors 115. Polymer 105 may be incorporated with silane, titanate, or aluminate coupling agents. In an embodiment, polymer 105 is incorporated with silane compounds to optimize polymer 105's adhering properties.

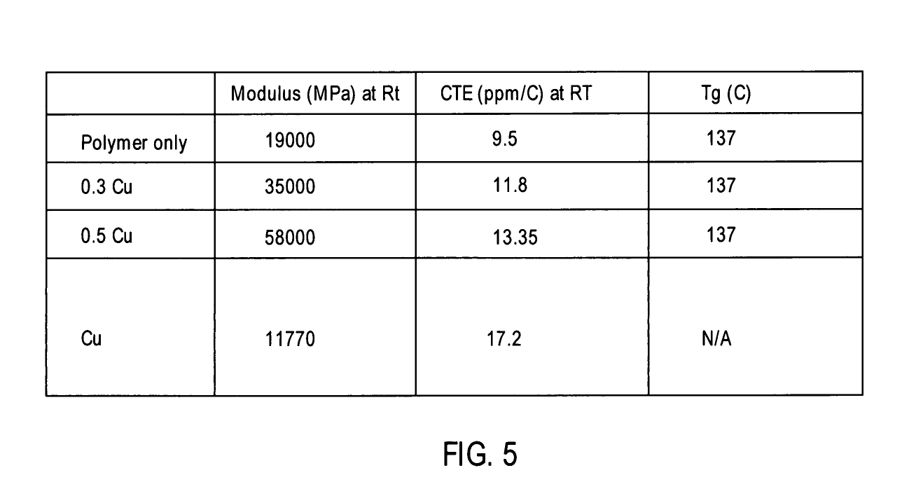

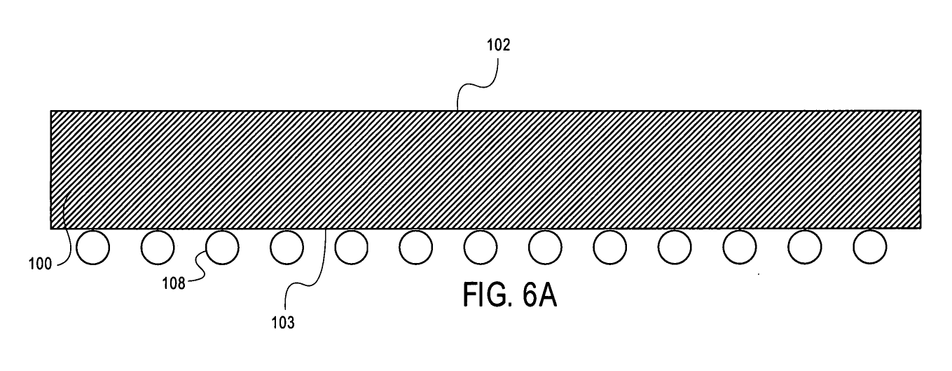

In an embodiment, increasing the effective Young's modulus of stiffener 101 and reducing the coefficient of thermal expansion (CTE) mismatch between stiffener 101 and package substrate 100 may decrease warpage in package substrate 100. In an embodiment, the effective Young's modulus of stiffener 101 is a function of the individual Young's modulus of reinforcing bars 110 and polymer 105. The effective Young's modulus of stiffener 101 may be increased by incorporating copper reinforcing bars 110 in polymer 105. The chart in FIG. 5 lists the respective Young's modulus for each specified weight fraction of copper reinforcing bars 110 incorporated in polymer 105. For example, according to FIG. 5, a 30 percent weight fraction of copper reinforcing bars 110 in polymer 105 increases the Young's modulus of polymer 105 from 19,000 MPa (at RT) to 35,000 MPa (at room temperature).

In an embodiment, reducing the coefficient of thermal expansion (CTE) mismatch between stiffener 101 and package substrate 100 further reduces warpage in package substrate 100. In an embodiment when copper reinforcing bars 110 are incorporated in polymer 105, the effective CTE of stiffener 101 increases which enhances the CTE compatibility with package substrate 100, as shown in the chart in FIG. 5. The typical CTE's of package substrate is 30 ppm/C.

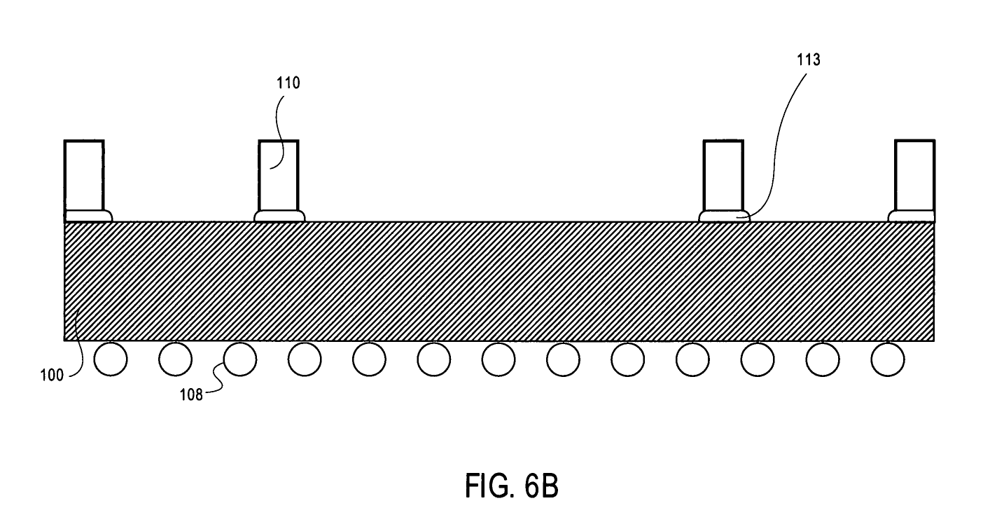

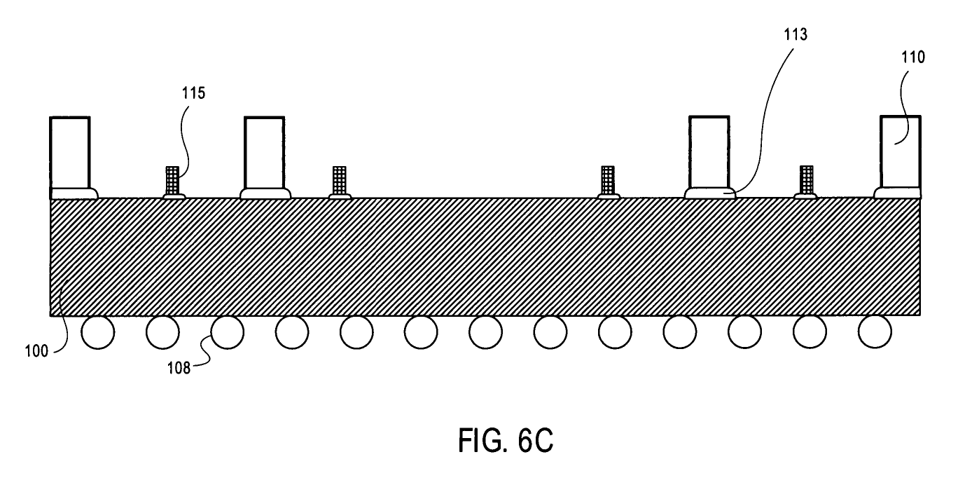

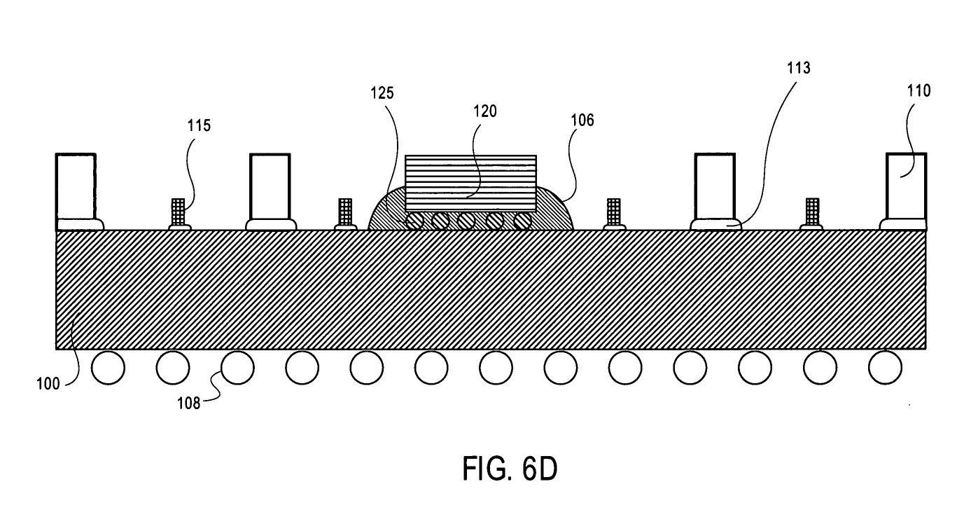

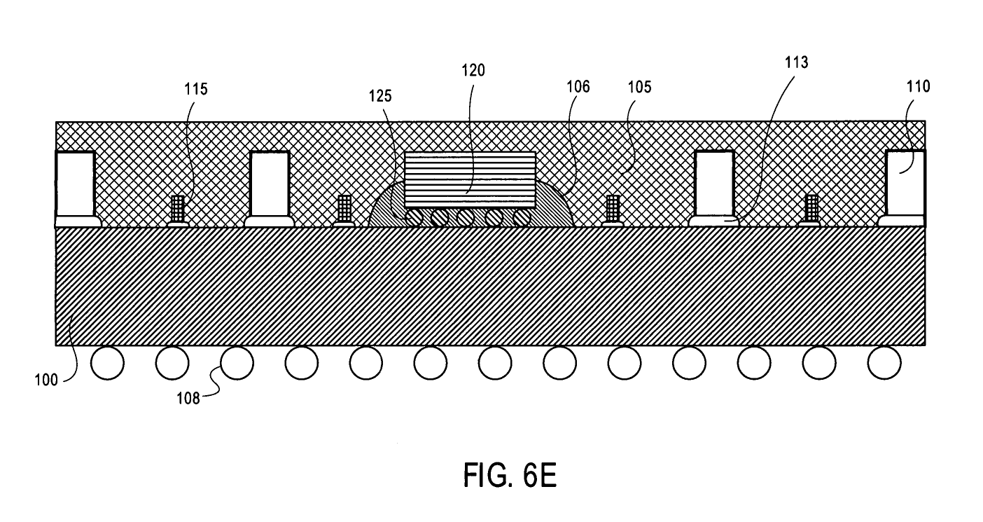

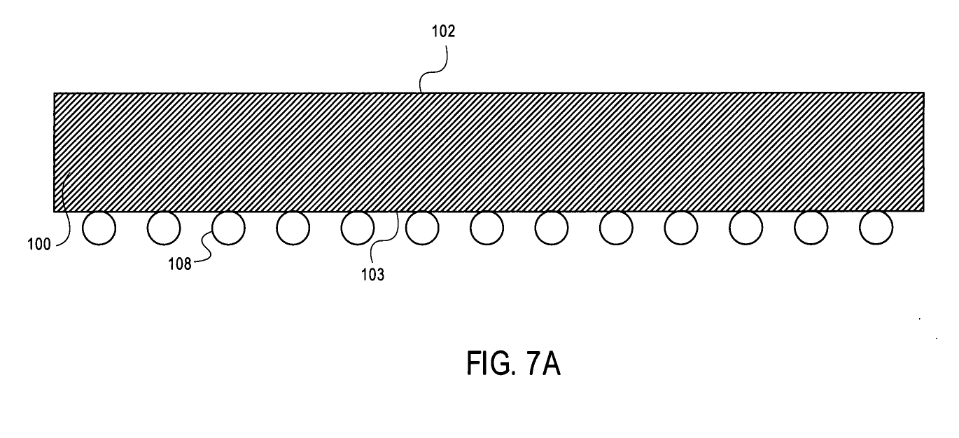

In an embodiment, an electronic package of the present invention may be manufactured by any process suitable in the art such that an electronic package features a stiffener including a reinforcing bars and a polymer. In an embodiment, an electronic package is manufactured according to the method illustrated in FIGS. 6A-6E.

To manufacture an electronic package according to an embodiment of the present invention as illustrated in FIGS. 6A-6E, first a package substrate 100 is provided as illustrated in FIG. 6A. In an embodiment, package substrate 100 functions to connect a microprocessor die to a motherboard and/or electrically couple the microprocessor die to other devices. In an embodiment, package substrate 100 has two sides, die-attach side 102 and contact side 103 as illustrated in FIG. 6A. In an embodiment, contact side 103 features a ball grid array 108 as further illustrated in FIG. 6A. In other embodiments, contact side 103 may feature a pin grid array. Package substrate 100 may include an organic or inorganic material.

Package substrate 100 may be coreless or a thin substrate and may be able to maintain mechanical durability and decrease warpage by use of a stiffener of the present invention. In an embodiment as illustrated in FIG. 6A, package substrate 100 is a coreless substrate which does not contain a core metal.

Next, in an embodiment, reinforcing bars 110 are pre-fabricated prior to attachment to package substrate 100. Reinforcing bars 110 may be pre-fabricated by an extrusion or welding process. In an embodiment, reinforcing bars 110 are pre-fabricated by a welding process. When reinforcing bars 110 are pre-fabricated, reinforcing bars 110 are subsequently attached to package substrate 100 using in room temperature adhesives or reflowing pre-attached solder alloy. In an embodiment as illustrated in FIG. 6B, pre-fabricated reinforcing bars 110 are coupled to package substrate 100 by a pre-attached solder alloy 113. In an embodiment, solder alloy 113 is reflowed to adhere reinforcing bars 110 to package substrate 100.

Next, in an embodiment, die side capacitors 115 are formed above the top surface of said package substrate 100 reinforcing bars 110 as illustrated in FIG. 6C. In an embodiment, die side capacitors 115 are formed on the top surface of said package substrate 100 by a reflow-solder alloy process.

Subsequently, a semiconductor die 120 is attached to package substrate 100 according to an embodiment as illustrated in FIG. 6D. Semiconductor die 120 may be attached to package substrate 100 by any method suitable in the art. In an embodiment, semiconductor die 120 is attached to package substrate 100 by a Control Collapse Chip Connect (C4) process as evident by bumps 125 illustrated in FIG. 6D. In an embodiment, an underfill material 106 is applied around bumps 125 and the area between semiconductor die 125 and package substrate 100. In an embodiment, underfill material 106 may increase the reliability of an electronic package by reducing thermal and mechanical induced stress, improve fatigue life, and seal out moisture.

Then, in an embodiment, a polymer 105 is applied over and between reinforcing bars 110 such that polymer 105 encapsulates semiconductor die 120, reinforcing bars 110 and die side capacitors 115 as illustrated in FIG. 6E. In other embodiments, polymer 105 does not encapsulate semiconductor die 120. In an embodiment, polymer 105 is applied by a jet dispense technique. In another embodiment, polymer 105 is applied by a stencil print process. Then, in an embodiment, polymer 105 is cured. Subsequently, in an embodiment, polymer 105 is cured at 175 degrees C for 2 hours.

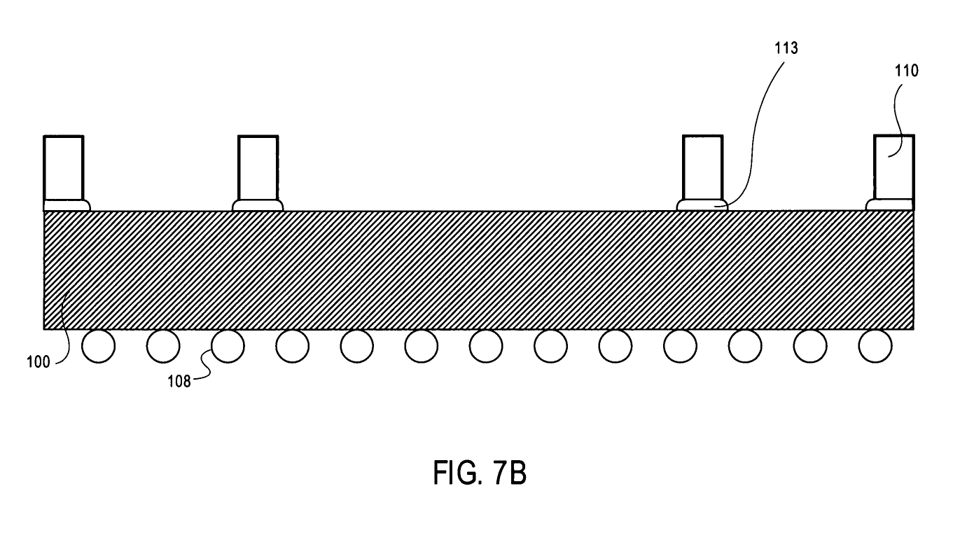

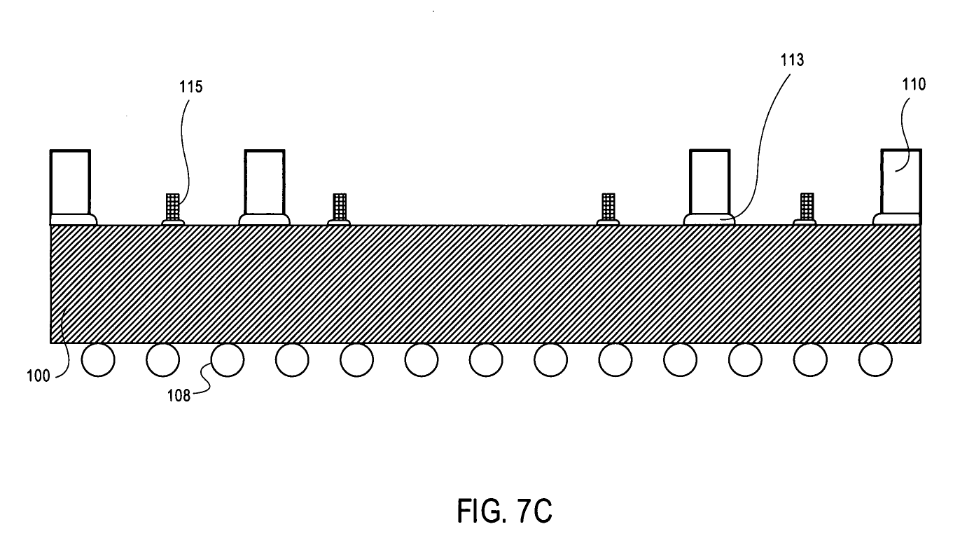

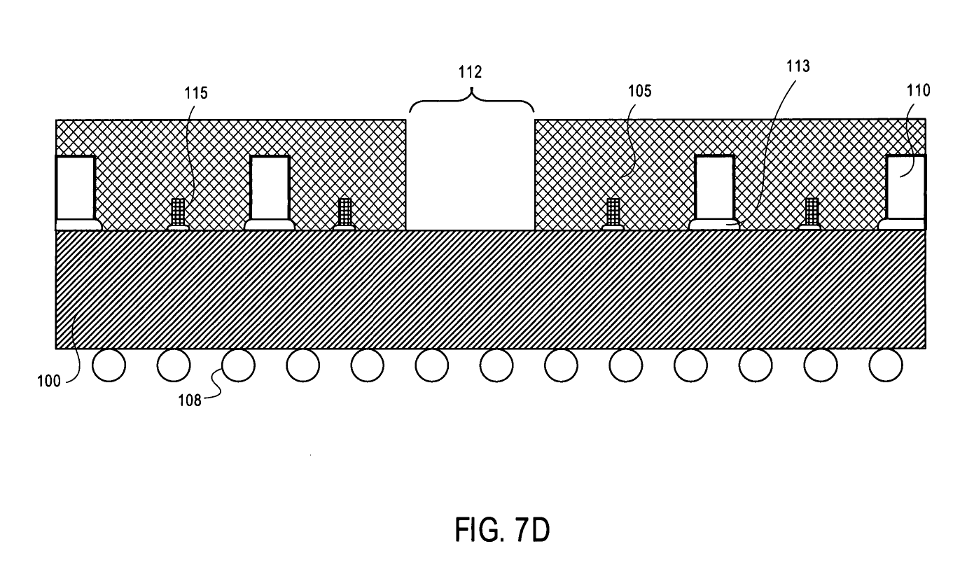

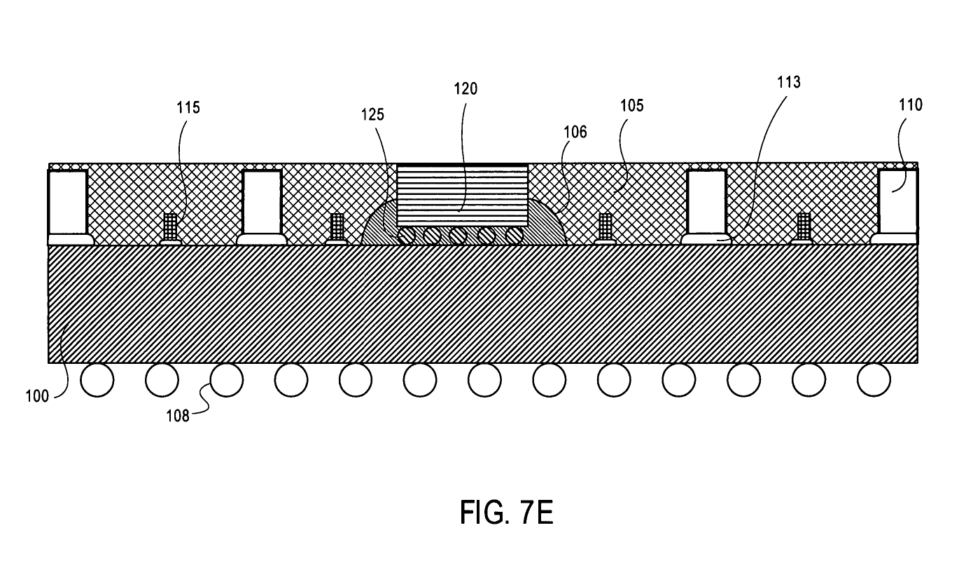

In an embodiment, an electronic package of the present invention may be manufactured according to the method illustrated in FIGS. 7A-7E. In an embodiment, first a package substrate 100 is provided as illustrated in FIG. 7A. In an embodiment, package substrate 100 has two sides, die-attach side 102 and contact side 103 as illustrated in FIG. 7A. In an embodiment, contact side 103 features a ball grid array 108 as further illustrated in FIG. 7A. In other embodiments, contact side 103 may feature a pin grid array.

Next, in an embodiment, reinforcing bars 110 are pre-fabricated prior to attachment to package substrate 100. Reinforcing bars 110 may be fabricated by an extrusion or welding process. In an embodiment, reinforcing bars 110 are fabricated by a welding process. When reinforcing bars 110 are pre-fabricated, reinforcing bars 110 are subsequently attached to package substrate 100 using adhesives or reflowing pre-attached solder alloy. In an embodiment as illustrated in FIG. 7B, pre-fabricated reinforcing bars 110 are coupled to package substrate 100 by a pre-attached solder alloy 113. In an embodiment, solder alloy 113 is reflowed to adhere reinforcing bars 110 to package substrate 110.

Subsequently, in an embodiment, die side capacitors 115 are formed on the die attach side of said package substrate 100 between reinforcing bars 110 as illustrated in FIG. 7C. In an embodiment, die side capacitors 115 are formed on the die attach side of package substrate 100 by a reflow-solder alloy process.

Then, in an embodiment, a polymer 105 is applied over and between reinforcing bars 110 and applied on die side capacitors 115 as illustrated in FIG. 7D. Polymer 105 may be applied by a jet dispense or stencil print process. In an embodiment, polymer 105 is not applied in the area where semiconductor die 120 will be attached to package substrate 100, reserved area 112. In other embodiments, polymer 105 is applied over the die attach side of package substrate 100 and the portion of polymer 105 in reserved area 112 is subsequently removed. Next, polymer 105 is cured according to a high temperature cross-linking process.

Next, a semiconductor die 120 is attached to package substrate 100 in reserved area 112 as illustrated in FIG. 7E. In an embodiment, reserved area 112 is near the center of package substrate 100. In other embodiments, reserved area 112 is not near the center of package substrate 100. After semiconductor die 120 is attached to package substrate 100, an underfill material 106 is applied around bumps 125 and in the area between semiconductor die 120 and package substrate 100.

1. An electronic package comprising:
a package substrate, wherein said package substrate has a die attach side and a contact side; and
a stiffener coupled to said die attach side of said package substrate, wherein said stiffener comprises a layout of reinforcing bars and a polymer; and
a semiconductor die coupled to said die attach side of said package substrate, wherein said semiconductor die is positioned in a cavity in said layout of reinforcing bars.

2. The electronic package of claim 1 further comprising die side capacitors affixed to said die attach side of said package substrate next to said reinforcing bars.

3. The electronic package of claim 1, wherein said polymer comprises an epoxy resin.

4. The electronic package of claim 1, wherein said reinforcing bars comprise a first reinforcing bar and a second reinforcing bar.

5. The reinforcing bars of claim 4, wherein said first reinforcing bar and said second reinforcing bar has a shape selected from the group consisting of cuboid and cylindrical.

6. The reinforcing bars of claim 4, wherein said first reinforcing bar and said second reinforcing bar are disposed in parallel on said die attach side of said package substrate.

7. The reinforcing bars of claim 4, wherein said first reinforcing bar and said second reinforcing bar are disposed as a mesh on said die attach side of said package substrate.

8. The electronic package of claim 1, wherein said polymer encapsulates said semiconductor die.

9. The electronic package of claim 1, wherein said reinforcing bars comprise a first level of reinforcing bars and a second level of reinforcing bars.

10. The electronic package of claim 9, wherein said first level of reinforcing bars has a first layout and said second level of reinforcing bars has a second layout.

11. The electronic package of claim 10, wherein said first layout and said second layout is selected from the group consisting of parallel and a mesh pattern.

12. An electronic package comprising:
a package substrate, wherein said package substrate has a die attach side and a contact side; and
a stiffener coupled to said die attach side of said package substrate, wherein said stiffener comprises a layout of reinforcing bars and an epoxy resin and wherein said layout of reinforcing bars comprise a first level of reinforcing bars and a second level of reinforcing bars and wherein said reinforcing bars have a cylindrical shape; and
die side capacitors affixed to said die attach side of said package substrate next to said first level of reinforcing bars; and
a semiconductor die coupled to said die attach side of said package substrate, wherein said semiconductor die is positioned in a cavity in said layout of reinforcement bars and wherein said semiconductor die is encapsulated in said epoxy resin.

13. The electronic package of claim 12, wherein said reinforcing bars comprise metal.

14. The electronic package of claim 12, wherein said first level consists of parallel reinforcing bars and said second level consists of a mesh of reinforcing bars.

15. A method comprising:
coupling reinforcing bars on a die attach side of a package substrate; and
coupling a semiconductor die on said die attach side of said package substrate, wherein said semiconductor die is positioned in a cavity in said layout of reinforcing bars; and
forming a polymer over said die attach side of package substrate, wherein said polymer encapsulates said reinforcing bars.

16. The method of claim 15 further comprising coupling die side capacitors to a die attach side of said package substrate.

17. The method of claim 16 further comprising encapsulating said semiconductor die.

18. The method of claim 15, wherein said die side capacitors are coupled to the die attach side of said package substrate by a reflow solder process.

19. The method of claim 15, wherein said polymer is formed over said die attach side of said package substrate by a jet dispense process.

20. A method comprising:
coupling reinforcing bars on the die attach side of a package substrate; and
forming a polymer, wherein said polymer encapsulates said reinforcing bars;
coupling a semiconductor die to said die attach side of said package substrate, wherein said semiconductor die is positioned in a cavity in said layout of reinforcing bars.

21. The method of claim 20 further comprising encapsulating said semiconductor die in said polymer.

22. The method of claim 20, wherein said polymer is formed by a method selected from the group consisting of jet dispensing, stencil printing, and transfer molding.

23. A method comprising:
coupling a layout of reinforcing bars on the die attach side of a package substrate by a reflow solder process; and
jet dispensing a polymer over the die attach side of said package substrate to encapsulate said reinforcing bars; and
coupling a semiconductor die to said die attach side of said package substrate by a controlled collapse chip connect process, wherein said semiconductor die is positioned in a cavity in said layout of reinforcing bars.

24. The method of claim 23, wherein said layout of reinforcement bars is a single mesh unit of reinforcing bars.

25. The method of claim 23, wherein said layout of reinforcement bars is a mesh of a plurality of connected reinforcing bars.
